(19) United States
(12) Patent Application Publication
(10) Pub. No.: US 2026/0264806 A1
(43) Pub. Date: Sep. 10, 2026

(54) Circuit board assembly for a drive unit of an electric bicycle, and mounting method

(71) Applicant: Brose Antriebstechnik GmbH & Co. Kommanditgesellschaft, Berlin, Berlin (DE)

(72) Inventors: Christoph EHEHALT-BOHM, Kurnach (DE); Stefanie PFRIEM, Gerbrunn (DE); Michael JACOB, Meura (DE); Robert FRIEDLAND, Strausberg (DE); Daniel HUCKSTADT, Berlin (DE)

(21) Appl. No.: 19/164,985

(22) PCT Filed: Mar. 11, 2024
(86) PCT No.: PCT/EP2024/056439

§ 371 Date: Sep. 12, 2025

(30) Foreign Application Priority Data
Mar. 14, 2023 (DE) 10 2023 106 362.6

(51) Int. Cl. B62M 6/80; B62J 45/20; B62M 6/50; H02K 7/116; H02K 11/33; H02K 21/16; H05K 1/14

(52) U.S. Cl. CPC B62M 6/80; B62J 45/20; B62M 6/50; H02K 7/116; H02K 11/33; H02K 21/16; H05K 1/144; H02K 2211/03; H05K 2201/042

(57) ABSTRACT

The proposed solution relates in particular to a circuit board assembly for a drive unit of an electric bicycle, said circuit board assembly comprising two interconnected circuit boards. The circuit board assembly comprises a circuit board holder to which one of the circuit boards is secured and by means of which the circuit boards are held with respect to one another at a distance specified by the circuit board holder.

### CROSS-REFERENCE TO RELATED APPLICATION

This application is a National Stage of International Application No. PCT/EP2024/056439 filed on Mar. 11, 2024, which claims priority from German Patent Application 10 2023 106 362.6, filed on Mar. 14, 2023. The contents of the above document are incorporated herein by reference in its entirety.

### BACKGROUND OF THE INVENTION

### FIELD OF THE INVENTION

The proposed solution relates in particular to a drive unit for an electric bicycle.

### Description of the Related Art

Drive units for electric bicycles with at least one electric motor drive are widely known. At least one electric motor drive is used here to provide a drive torque generated by external force operation at an output element of the drive unit. The output element is then coupled, for example, to a force transmission element which is connected to a rear wheel of the electric bicycle via a transmission member, such as a belt or a chain. The drive torque generated by external force operation is typically provided in addition to a drive torque generated by muscle force operation that is introduced at a pedal shaft via pedals.

The output element and the force transmission element are regularly provided on a pedal shaft assembly comprising the pedal shaft with a freewheel. This supports a compact configuration of the drive unit, since the rotation axis of the pedal shaft is identical to the rotation axes of the output element and the force transmission element.

At least one electric motor having a stator and a rotor is typically provided for the electric motor drive of the drive unit. The stator is accommodated at a housing part of the drive unit and supported to be rotationally fixed. The housing part forms a bearing location for this purpose, for example in the form of a bearing pot, at which the stator—possibly together with the rotor already pre-assembled to it—is arranged during assembly of the drive unit.

In a housing of the drive unit, which in particular accommodates the electric motor drive, electronic components, such as one or more circuit boards, are typically also accommodated. The electronic components then serve, for example, to supply the electric motor drive with current and to accommodate sensors and circuit components for controlling the drive unit. If two or more circuit boards are to be accommodated in a housing of the drive unit, there is often the problem of positioning these circuit boards as intended in relation to each other and holding them in a specific position while further components are assembled to a housing part of the drive unit. A process reliable assembly of the drive unit can therefore be very difficult to realize when two or more circuit boards are to be accommodated in one housing.

### SUMMARY OF THE INVENTION

Against this background, there is a need for an improved means of arranging two or more circuit boards in a housing for a drive unit in this regard, in particular for a drive unit of an electric bicycle.

The proposed solution provides in particular for a circuit board assembly with two circuit boards connected to each other, at least one of which is fixed to a circuit board holder, via which the circuit boards are held at a distance from each other predetermined by the circuit board holder. Via the circuit board holder thus the two circuit boards are positioned at a predetermined distance from each other in such a way that the two circuit boards are supported against each other by the circuit board holder and prevented from tilting relative to each other. A circuit board assembly pre-assembled with the circuit board holder can thus be installed in a housing of the drive unit in a process-reliable manner, since a position of the two circuit boards relative to each other is already secured by the circuit board holder.

For example, the circuit board holder has at least one spacer element that specifies the distance at which the two circuit boards are held relative to each other. A corresponding spacer element is located, for example, on an upper side of one circuit board and on a lower side of the other circuit board. In this embodiment, the spacer element is therefore arranged between portions of the circuit boards in order to, on the one hand ensure the distance between the circuit boards arranged one above the other and, on the other hand, to support the circuit boards against each other.

For example, at least one of the circuit boards can be connected to the at least one spacer element in a form-fitting manner. Via a form-fitting connection between a circuit board and the circuit board holder, for example, a pre-assembly of the circuit board assembly can be facilitated and/or a specific orientation of the respective circuit board with respect to the circuit board holder can be ensured with relative ease. A corresponding form-fit may in particular include an element of the respective circuit board and the spacer element of the circuit board holder being brought into contact with each other in a form-fitting manner without the need for an additional fastening element. For example, a form-fit element of the circuit board may be plugged onto the spacer element for a form-fit connection between at least one of the circuit boards and the at least one spacer element. The form-fit element may, for example, be an integral constituent part of the respective circuit board. In one embodiment, for example, a form-fit element of a circuit board, in particular a form-fit element formed on the respective circuit board, is inserted into an opening of the spacer element.

Alternatively or additionally, the at least one spacer element of the circuit board holder can be formed with a through-opening, for example in the form of a through-hole, which is provided for the passage of a fastening element (of the circuit board assembly) for fixing the circuit board assembly to a carrier component. The spacer element of the circuit board holder thus serves not only to space apart and support the two circuit boards, but also to fix the circuit board assembly comprising the two circuit boards and the circuit board holder to a carrier component. To fix the circuit board assembly to the carrier component, a fastening element, such as a screw or a bolt (as part of the circuit board assembly), is provided, which passes through the through opening of the spacer element. In this way, a circuit board assembly pre-assembled with the two circuit boards and the circuit board holder can be fixed to a carrier component of the drive unit using the spacer element of the circuit board holder. A corresponding carrier component is formed, for example, by a housing part of the drive unit or by a component of the drive unit already installed in such a housing component.

In one possible embodiment, the at least one spacer element of the circuit board holder is sleeve-shaped.

In principle, the circuit board holder can comprise several (at least two) spacer elements which are connected to each other via a connecting structure of the circuit board holder. The two circuit boards can be supported against each other at several locations via several spacer elements of the circuit board holder, thereby increasing the rigidity of the circuit board assembly. In addition, via several spacer elements, each of which is brought into contact with both the one and the other circuit board, an intended orientation of the two circuit boards relative to each other and with respect to the circuit board holder can be ensured more easily. In particular, in combination with several form-fit elements on the circuit board side, which are to be connected to the several spacer elements, in particular to be plugged onto them, it is achievable that the two circuit boards are only connectable to the circuit board holder in a unique orientation relative to each other.

In one embodiment, the two circuit boards are not only physically connected to each other via the circuit board holder, but are also electrically connected to each other by a connecting element. Electrical signals can therefore be transmitted between the two circuit boards via the at least one connecting element. For example, such a connecting element is formed by at least one connecting plug. Such a connecting plug can be provided on one of the circuit boards so that, with the assembly of the circuit board assembly, the other circuit board is plugged onto this connecting plug, thereby establishing the electrical connection.

In one embodiment, it can be provided that the connecting element provided for the electrical connection is passed through the circuit board holder. The connecting element between the two circuit boards is therefore provided in an area of the circuit board assembly in which the circuit board holder is arranged between the two circuit boards. For example, the circuit board holder may comprise an opening in which at least one portion of the connecting element is received in a form-fitting manner.

In an embodiment in which a connecting element provided for the electrical connection between the two circuit boards is received in an opening of the circuit board holder, a connecting element can also be used to ensure (additionally, if necessary) that the two circuit boards can only be assembled in a specific orientation with respect to the circuit board holder and relative to each other. The opening in which at least a portion of the connecting element is accommodated in a form-fitting manner can then fulfil the function of a positioning opening, by the connecting element only being passable through the opening in a specific orientation, and the circuit board holder with its opening can therefore only be assembled in a predetermined orientation to the circuit board already having the connecting element. After assembling the circuit board holder to this circuit board, the other circuit board is then assembled to the circuit board holder and connected to the connecting element in order to electrically couple the circuit boards to each other. Since, in this case, the other circuit board is only connectable to the (possibly rigid) connecting element in a specific orientation via corresponding contacts and/or a connecting sleeve on the other circuit board, the additional circuit board can therefore also only be assembled in a specific orientation with respect to the circuit board holder.

The opening for a connecting element can be formed on the circuit board holder, for example, on a connecting structure mentioned above, via which several spacer elements of the circuit board holder are connected to each other.

Part of the proposed solution is also a drive unit for an electric bicycle, which comprises an electric motor drive and an embodiment of a proposed circuit board assembly.

A plug connector portion, which comprises one or several plug connectors for connecting the drive unit to a current supply and/or a higher-level control electronics on the electric bicycle, may be provided on one of the circuit boards of the circuit board assembly. Alternatively, or additionally, at least parts of a sensor technology, via which a torque (e.g., at a pedal shaft of the drive unit) is determinable, and/or an inertial measurement unit may be provided on at least one of the circuit boards.

In one embodiment, the electric motor drive of the drive unit comprises a rotor rotatable about a rotor axis and a transmission assembly whose transmission elements are coupled to the rotor of the electric motor drive. In order to achieve a compact arrangement of the circuit board assembly in a housing of such a drive unit, it may be provided, for example, that the circuit board assembly is fixed to a transmission carrier on which the transmission elements of the transmission assembly are at least partially supported, in particular rotatably supported. A corresponding transmission carrier in such a drive unit therefore is responsible for supporting the transmission elements and supporting the circuit board assembly.

To facilitate the assembly of the circuit board assembly, it may also be provided in this context that the at least one spacer element of the circuit board holder is formed with a through opening through which a fastening element passes, via which the circuit board assembly is fixed to the transmission carrier. The circuit board assembly can therefore be fixed to the transmission carrier of the drive unit during assembly by means of a fastening element passing through the spacer element.

The proposed solution also comprises a method for assembling a circuit board assembly to a housing part of a drive unit for an electric bicycle. In this case, it is provided that the circuit board assembly with two circuit boards and a circuit board holder is pre-assembled by fixing the two circuit boards to the circuit board holder and holding them at a distance from each other predetermined by the circuit board holder, and then assembling the pre-assembled circuit board assembly to the housing part of the drive unit.

The two circuit boards and the circuit board holder (and, if necessary, other components) can thus form a pre-assembled unit in which the two circuit boards are already orientated with respect to each other and supported against each other by the circuit board holder before this unit is assembled to the housing part of the drive unit.

In particular, an embodiment of a proposed circuit board assembly can be used for a proposed assembly method. The features and advantages described above and below for embodiments of a proposed circuit board assembly therefore also apply to embodiments of a proposed assembly method and vice versa.

For example, within an embodiment of a proposed assembly method it may be provided that the drive unit comprises an electric motor drive with a rotor rotatable about a rotor axis and a transmission assembly whose transmission elements are coupled to the rotor and are at least partially assembled to a transmission carrier of the transmission assembly. The transmission carrier can be assembled to the housing part before the pre-assembled circuit board assembly, so that the pre-assembled circuit board assembly is fixed to the transmission carrier during the assembly of the drive unit.

### BRIEF DESCRIPTION OF THE DRAWINGS

The accompanying figures exemplarily illustrate possible embodiments of the proposed solution.

FIGS. 1A-1B show an embodiment of a proposed drive unit in perspective view with a view onto different longitudinal sides;

FIG. 2A shows a first housing part of the housing of the drive unit of the FIGS. 1A and 1B with a view onto its outside;

FIG. 2B shows the first housing part of FIG. 2A with a view onto its inner side;

FIG. 3 shows the first housing part with the stator of an electric motor drive of the drive unit assembled thereto;

FIG. 4 shows the first housing part in a subsequent assembly step, in which a rotor is assembled to the first housing part already having the stator;

FIG. 5 shows the first housing part with the stator assembled thereto and the rotor assembled thereto;

FIG. 6 shows the first housing part in a subsequent assembly step, in which a transmission assembly and a bearing shield are assembled to the first housing part already having the stator and the rotor;

FIG. 7 shows the first housing part with the transmission assembly fixed thereto and the bearing shield fixed to the transmission assembly;

FIG. 8 shows the first housing part with a pre-assembled circuit board assembly to be attached thereto, according to the proposed solution;

FIG. 9 shows the first housing part with the circuit board assembly assembled thereto and at least partially fixed to a transmission carrier of the transmission assembly;

FIG. 10 shows the circuit board assembly in an exploded illustration, with a first circuit board, a circuit board holder, and a second circuit board;

FIG. 11 shows a circuit board holder of a further embodiment for a circuit board assembly in a perspective view;

FIG. 12 shows the circuit board assembly with the circuit board holder of the FIG. 11 in a state of being assembled and fixed to the transmission carrier.

### DETAILED DESCRIPTION OF THE DRAWINGS

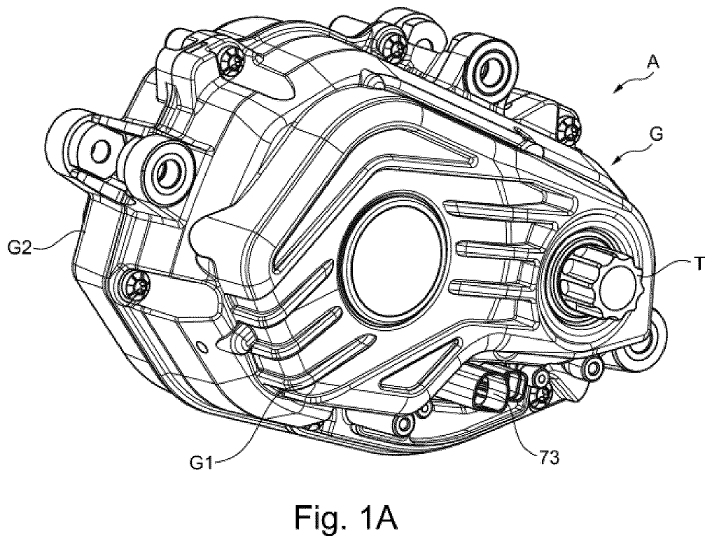

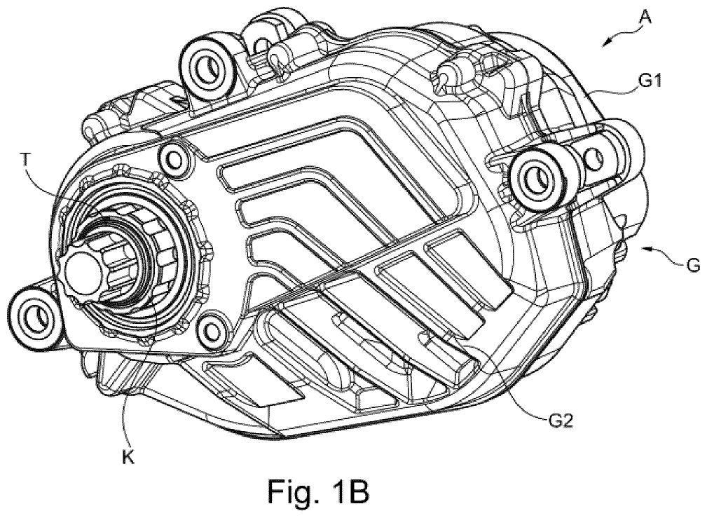

FIGS. 1A and 1B show a drive unit A for an electric bicycle in different perspective views looking at two different side surfaces. The drive unit A comprises a housing G that accommodates electronic and mechanical components. This housing G comprises two interconnected first and second housing parts G1 and G2, each of which defines one half of the housing.

The ends of a pedal shaft T protrude from the housing G on both sides. Pedals can be attached to these ends so that, after proper assembly of the drive unit A to an electric bicycle, a drive torque can be introduced at the pedal shaft T by muscle force operation to drive the electric bicycle. Via a force transmission element K on the pedal shaft T, in particular, a torque generated by muscle force operation is outputtable, e.g., with the aid of a belt wheel or chainring connected in a rotationally fixed manner to the force transmission element K, and transmittable to a rear wheel of an electric bicycle via a transmission member such as a belt or chain. In addition, a torque generated by an external force operation can be applied to the force transmission element K, which is provided by an electric motor drive accommodated in the housing G and transmitted to the force transmission element K via a transmission also accommodated in the housing G.

On one side formed by the first housing part G1, a plug connector portion ST of a circuit board assembly 7 leading out of the interior of the housing G is visible. This plug connector portion ST protrudes through a plug opening O7 to the outside and has one or more plug connectors for connecting the drive unit A to a current supply and/or a higher-level control electronics on the electric bicycle.

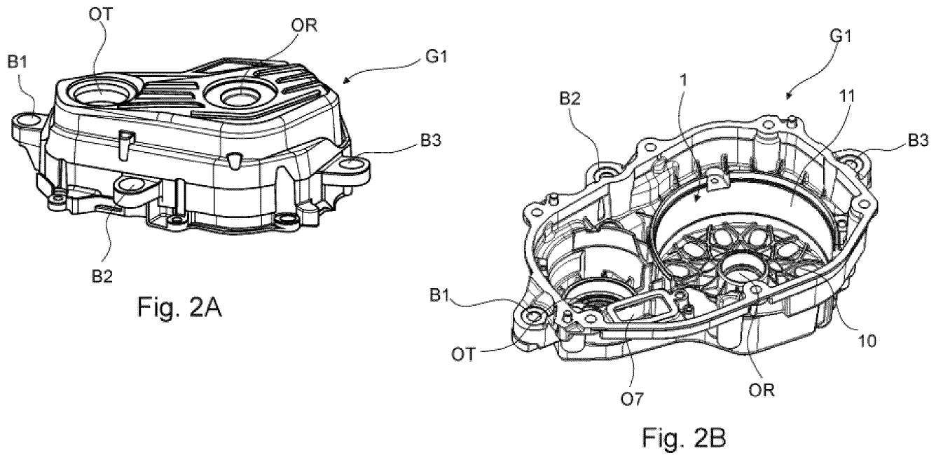

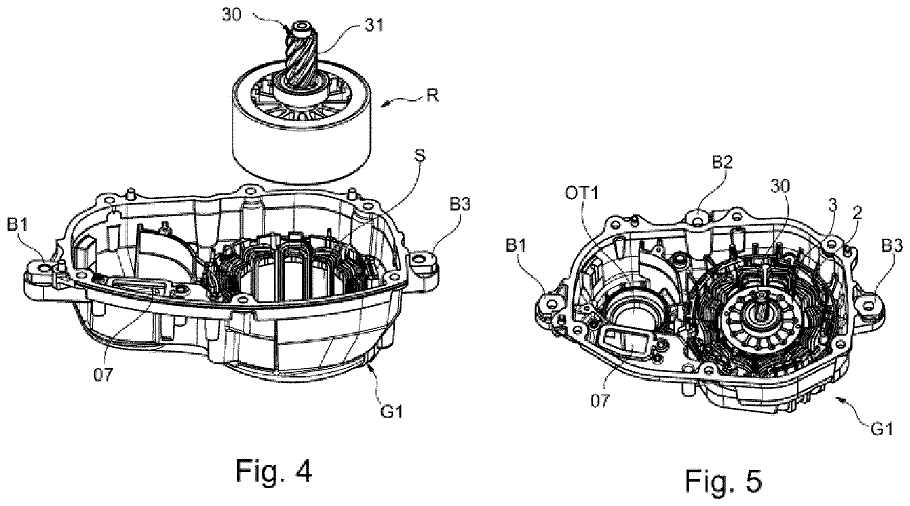

The FIGS. 2A and 2B show the first housing part G1 for an embodiment of a proposed drive unit A in different views in an individual representation. The first housing part G1 is formed as a housing half, which together with the second housing part G2 defines a housing space in which electronic and mechanical components of the drive unit A are to be accommodated. For connection to the second housing part G2, and thus in this case a second housing half, the first housing part G1 has several (at least two)—in this case three—fastening locations B1, B2, and B3 distributed on an outer circumference of the first housing part G1. In addition, a housing opening OT for the pedal shaft T of the drive unit A and a bearing opening OR for a rotor shaft 30 of an electric motor drive of the drive unit A are formed on the first housing part G1. The rotor shaft 30 is part of a rotor 3, which is rotatable relative to a stator 2 of the electric motor drive around a rotor axis that coincides with the shaft axis of the rotor shaft 30 in order to provide a drive torque generated by an external force operation (see FIGS. 4 to 7 in particular).

As can be seen in particular looking at the inside of the first housing part G1 according to FIG. 2B, the first housing part G1 forms a (motor) bearing location 1 with a bearing pot. The bearing location 1 is intended in particular for the arrangement of the stator 2 of the electric motor drive.

The pot-shaped bearing location 1 or bearing location formed with the bearing pot within the first housing part G1 has an inner wall 11 that revolves completely around a circular line around the bearing opening OR for the rotor shaft 30 (and thus around a rotor axis of the rotor 3 defined by the rotor shaft 30). This inner wall 11 runs perpendicular to a bottom 10 of the bearing location 1, which in this case is exemplarily formed with ribs extending in a blossom-like shape with respect to the bearing opening OR.

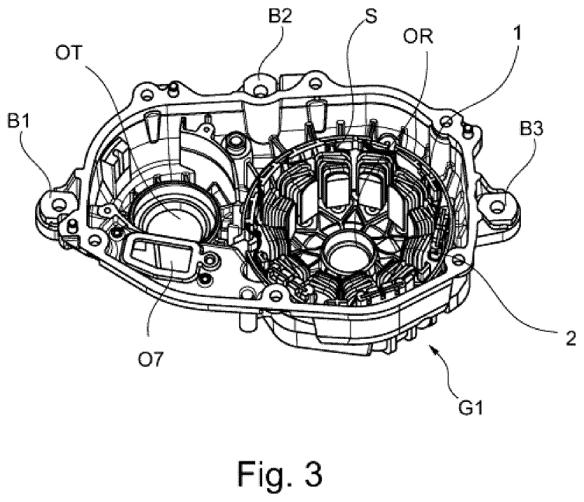

In the FIG. 3, the stator 2 comprising several coils 23 is inserted into the first housing part G1 and fixed in place during the assembly of the drive unit A. In a subsequent assembly step, a multi-part rotor 3 is inserted into the stator 2 and thus into the first housing part G1, according to the FIG. 4. The rotor 3 comprises a rotor unit with sheet-clad magnets and a rotor shaft 30. A (motor) pinion 31 is formed on the rotor shaft 30 or fixed to it in a rotationally fixed manner so that a drive torque generated by the electric motor drive 2, 3 can be transmitted via the pinion 31.

In the state of being assembled as intended of the drive unit A, an externally operated generated drive torque is transmitted from the pinion 31 to a transmission that is coupled to the force transmission element K. In the present case, at least a part of this transmission is provided by a pre-assemblable transmission assembly 4. This transmission assembly 4 is assembled to the first housing part G1 after the stator 2 and the rotor 3 have already been arranged at the bearing location 1 as intended, as illustrated in FIG. 5.

In the present case, several intermeshing gear wheels are rotatably supported on a transmission carrier 40 of the transmission assembly 4, in particular a gear wheel intended for meshing with the pinion 31 when the transmission assembly 4 is assembled to the first housing part G1 as intended. The corresponding gear wheels of the transmission can be pre-assembled to the transmission carrier 40.

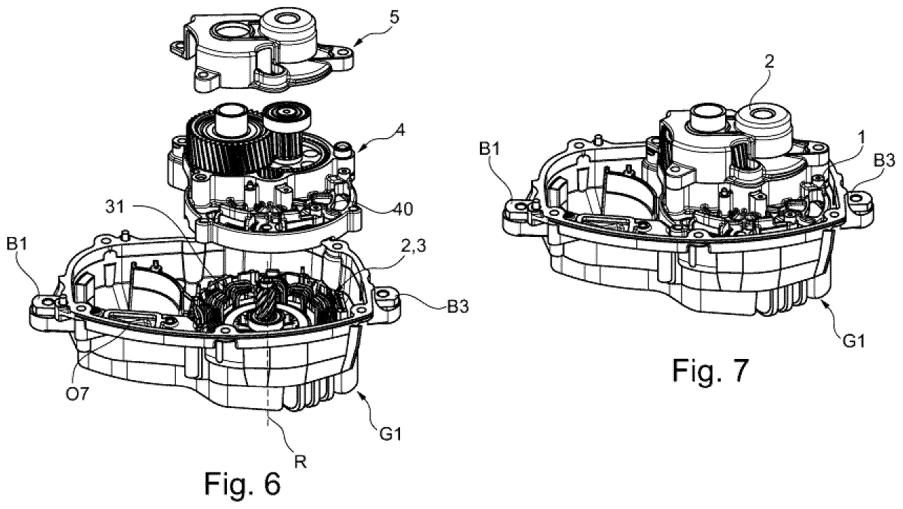

If the transmission assembly 4 is completely pre-assembled, it is assembled to the first housing part G1 in accordance with the assembly step shown in the FIG. 6 and fixed in place inside the first housing part G1 using fastening elements, for example in the form of screws or bolts. A bearing shield 5 is then arranged on and fixed to the transmission assembly 4 inserted into the first housing part G1 in this way.

After the assembly of further mechanical and electronic components to the first housing part G1, the second housing part G2 is attached to and fixed to the first housing part G1. Thereby, the housing space of the housing G, which accommodates the transmission assembly 4 and the motor drive 2, 3 is closed in a sealed manner.

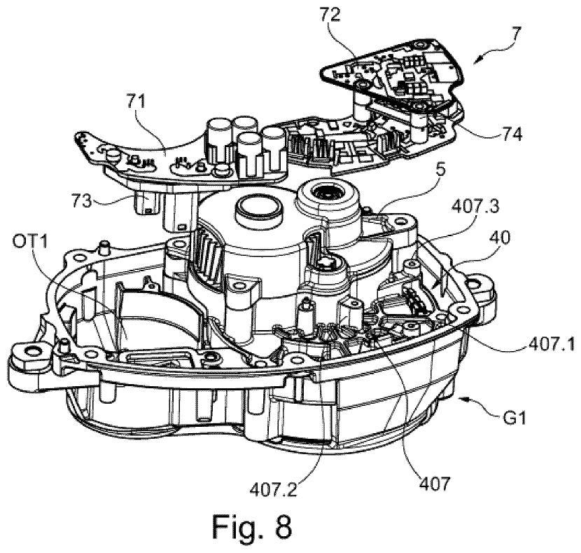

As illustrated in particular according to the FIGS. 8 to 10, the components still assembled to the first housing part G1 before the housing space is closed include the circuit board assembly 7 comprising the plug connector portion 73.

The circuit board assembly 7 comprises a first (main) circuit board and a second (additional) circuit board, between which a circuit board holder 74 is arranged in order to support the two circuit boards 71, 72 against each other and to position them at a distance from each other predetermined via the circuit board holder 74 (see FIG. 8). The first circuit board 71 is equipped with at least one torque sensor and the plug connector portion 73. The second circuit board 72, which only makes up a fraction of the area of the first circuit board 71, carries, for example, a rotor posture sensor and/or an inertial measurement unit. The two circuit boards 71 and 72 thus serve in the present case to supply current to the electric motor drive 2, 3 and to electronically control the drive unit.

The circuit board assembly 7, which is pre-assembled with the circuit board holder 74, in the present case, is assembled to the first housing part G1 after the transmission assembly 4 has already been attached there. The transmission carrier 40 already arranged in the first housing part G1 forms a bearing portion 407 to which the circuit board assembly 7 is fixed. For this purpose, the first larger circuit board 71 is fixed at several connection locations of the bearing portion 407, which are defined by holes 407.1, 407.2, and 407.3 in the transmission carrier 40. In the present case, a part of the first circuit board 71 is also fixed directly to the first housing part G1 and, for this purpose, to connection locations formed by the first housing part G1.

The intended arrangement of the circuit board assembly 7 on the transmission carrier 40 is accompanied by the insertion of the plug connector portion 73 into the housing-side plug opening O7, so that the plug connector portion 73 protrudes from the inside of the first housing part G1 to the outside when the circuit board assembly 7 has been arranged and fixed to the first housing part G1.

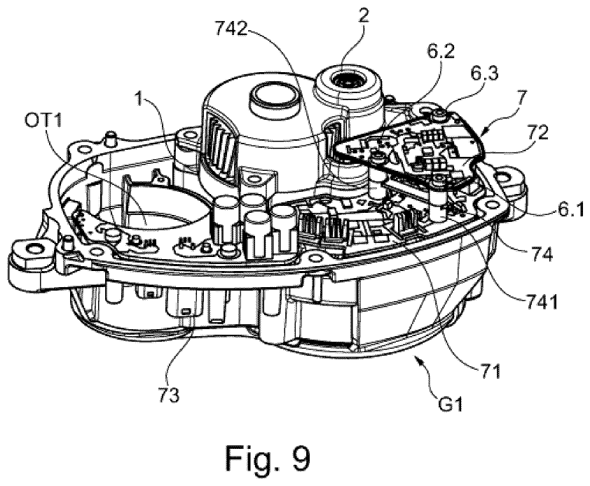

The fixing of the circuit board assembly 7 to the transmission carrier 40, which acts as a carrier component, is performed using the circuit board holder 74. The circuit board holder 74 comprises several—in this case three—spacer elements in the form of spacer sleeves 741, 742, 743. These spacer sleeves 741, 742, 743 define the distance between the two circuit boards 71 and 72 and each comprise a through opening through which a fastening element in the form of a fastening screw 6.1, 6.2, 6.3 can pass in order to fix the circuit board assembly 7 to the holes 407.1, 407.2, and 407.3 of the bearing portion 407 on the transmission carrier side, as shown in the FIG. 9.

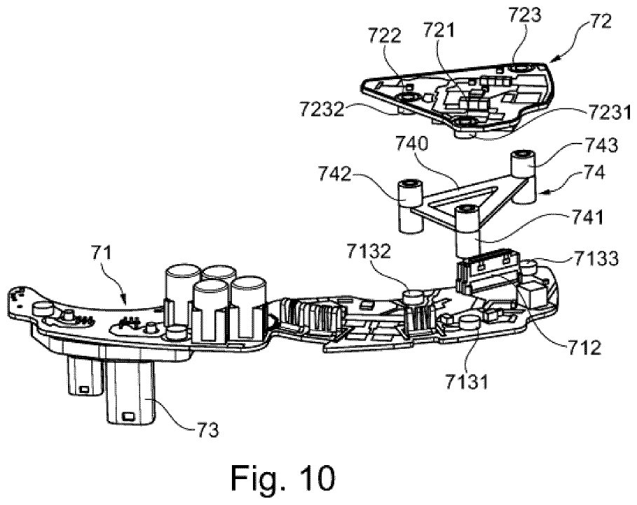

From the exploded view of the FIG. 10 it is apparent that both the first larger circuit board 71 and the second smaller (additional) circuit board 72 comprise several form-fit elements via which the circuit boards 71 and 72 can be connected to the circuit board holder 74 in a form-fitting manner before the fastening screws 6.1, 6.2, and 6.3 are assembled. The form-fitting elements are formed on the first circuit board 71 by insertion sleeves 7131, 7132, and 7133 protruding on its upper side. On the lower side of the second circuit board 72 facing the first circuit board 71, form-fit elements are also provided in the form of protruding insertion sleeves, two of which, 7231 and 7232, are visible in the exploded view of the FIG. 10. Alternatively, only holes may be formed in the circuit board 71 at the locations of the insertion sleeves 7131, 7132, 7133.

The insertion sleeves 7131, 7132, 7133, and 7231, 7232 are each inserted into an end side opening of an associated spacer sleeve 741, 742, and 743 of the circuit board holder 74. Via the three spacer sleeves 741, 742, and 743 in the present case connected via a triangularly shaped connecting structure 740 in a top view, the first and second circuit boards 71 and 72 are connectable to each other in a predetermined orientation relative to each other and relative to the circuit board holder 74, in particular without the use of tools. By being plugged together, the first and second circuit boards 71 and 72 and the circuit board holder 74 can thus form a pre-assembled unit that is assembled to the first housing part G1.

For example, it may be provided that the circuit board holder 74 is first plugged onto the upper side of the first circuit board 71. The second circuit board 72 is then plugged onto the circuit board holder 74. Of course, it is also possible to first plug the circuit board holder 74 onto the smaller second circuit board 72 before plugging the circuit board holder 74 with the second circuit board 72 onto the first circuit board 71. In any case, the connection of the two circuit boards 71 and 72 to the circuit board holder 74 is accompanied by a connecting element in the form of a connecting plug 712 electrically coupling the two circuit boards 71 and 72 to each other. In the exemplarily illustrated embodiment, the connecting plug 712 is part of the first circuit board 71, to which the second circuit board 72 is plugged or which is plugged to the second circuit board 72.

After placement of the circuit board assembly 7 to the transmission carrier 40, one of the fastening screws 6.1, 6.2, and 6.3 can be respectively inserted into one the fastening openings 721, 722, and 723 provided on an upper side of the second circuit board 72, which each open into one of the insertion sleeves of the second circuit board 72. A fastening screw 6.1, 6.2 or 6.3 passing the respective spacer sleeve 741, 742, or 743 and the respective insertion sleeve 7131, 7132 or 7133 of the other, first circuit board 71 can then be screwed into an associated hole 407.1, 407.2 or 407.3 of the transmission carrier 40.

After assembling the circuit board assembly 7 to the first housing part G1, the two circuit boards 71 and 72 are fixed in their position relative to each other by the circuit board holder 74 and further supported against each other. In this way, the circuit boards 71, 72 cannot tilt afterwards even when other components, and in particular the second housing part G2, are subsequently assembled to the first housing part G1. In particular, for the assembly of the drive unit A, further components can subsequently be brought into contact with portions of the circuit board assembly 7 in a process-reliable manner without having to fear any shift of the circuit boards 71, 72, in particular relative to each other.

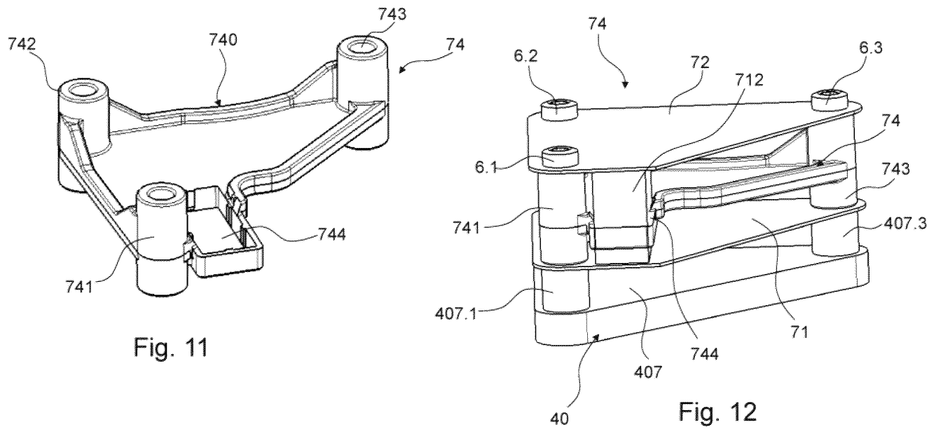

In an embodiment according to FIGS. 11 and 12, the circuit board holder 74 is configured differently for supporting and connecting the two circuit boards 71 and 72. If, in the embodiment of FIGS. 8 to 10, the connecting structure 740 connecting the spacer sleeves 741, 742 and 743 is formed with three struts that border a central triangular opening, in the embodiment shown in FIGS. 11 and 12, the connecting structure 740 is formed with a continuous connecting surface between the three spacer sleeves 741, 742, 743. A plug and positioning opening 744 is formed in this connecting surface of the connecting structure 740, in which the connecting plug 712 is accommodated in a form-fitting manner. In the present case, the circuit board holder 74 can only be assembled to the circuit boards 71, 72 in one orientation with respect to the connecting plug 712, so that via the plug and positioning opening 744 for the connecting plug 512 a unique orientation of the circuit board holder 74 with respect to the two circuit boards 71 and 72 is predetermined.

Considering the perspective view in excerpts of the FIG. 12, it is in particular illustrated how the spacer sleeves 741, 742, and 743, after being placed onto the bearing portion 407 of the transmission carrier 40, are aligned with the bores 407.1, 407.2, and 407.3, so that fastening screws 6.1, 6.2, and 6.3 inserted through the fastening openings 721, 722, and 723 of the second circuit board 72 can pass through the spacer sleeves 741, 742 and 743 of the circuit board holder 74 and can be screwed into the bores 407.1, 407.2, and 407.3 in order to fix the pre-assembled circuit board assembly 7 to the gear carrier 40.

### LIST OF REFERENCE SIGNS

1 Bearing location
10 Bottom
11 Side wall
2 Stator
23 Coil
3 Rotor
30 Rotor shaft
31 (Motor) pinion
4 Transmission assembly
40 Transmission carrier (carrier component)
407 Bearing portion
407.1, 407.2, 407.3 Bore (connection location)
5 Bearing shield
6.1, 6.2, 6.3 Fastening screw
7 Circuit board assembly
71 (Main) circuit board
712 Connecting plug (connecting element)
7131, 7132, 7133 Insertion sleeve (form-fit element)
72 (Additional) circuit board
721, 722, 723 Fastening opening
7231, 7232 Insertion sleeve (form-fit element)
73 Plug connector portion
74 Circuit board holder
740 Connection structure
741, 742, 743 Spacer sleeve (dome with bore)
744 Plug and positioning opening
A Drive unit
B1-B3 Connection location
G Housing
G1, G2 Housing half (housing part)
K Force transmission element
O7 Plug opening
OR Bearing opening for rotor shaft
OT Housing opening for pedal shaft
T pedal shaft (assembly)

1. A circuit board assembly for a drive unit of an electric bicycle, which comprises two circuit boards connected to each other,
the circuit board assembly comprises a circuit board holder, at which one of the circuit boards is fixed and via which the circuit boards are held at a distance from each other predetermined by the circuit board holder.

2. The circuit board assembly according to claim 1, wherein the circuit board holder has at least one spacer element that specifies the distance at which the two circuit boards are held relative to each other.

3. The circuit board assembly according to claim 2, wherein at least one of the circuit boards can be connected to the at least one spacer element in a form-fitting manner.

4. The circuit board assembly according to claim 3, wherein a form-fit element of the circuit board may be plugged onto the spacer element for a form-fit connection between at least one of the circuit boards and the at least one spacer element.

5. The circuit board assembly according to claim 4, wherein the form-fit element is inserted into an opening of the spacer element.

6. The circuit board assembly according to claim 2, wherein the at least one spacer element is formed with a through opening, which is provided for the passage of a fastening element for fixing the circuit board assembly to a carrier component.

7. The circuit board assembly according to claim 6, wherein the at least one spacer element is sleeve-shaped.

8. The circuit board assembly according to claim 2, wherein the circuit board holder comprises several spacer elements which are connected to each other via a connecting structure of the circuit board holder.

9. The circuit board assembly according to claim 1, wherein the two circuit boards are electrically connected to each other by a connecting element.

10. The circuit board assembly according to claim 9, wherein the connecting element is passed through the circuit board holder.

11. The circuit board assembly according to claim 10, wherein the circuit board holder comprises an opening in which at least one portion of the connecting element is received in a form-fitting manner.

12. The circuit board assembly according to claim 8, wherein the opening for the connecting element is formed on the connecting structure.

13. The circuit board assembly according to claim 9, wherein the connecting element is formed by at least one connecting plug.

14. A drive unit for an electric bicycle, having an electric motor drive and a circuit board assembly according to one of the preceding claims.

15. The drive unit according to claim 14, wherein a plug connector portion, which comprises one or several plug connectors for connecting the drive unit to a current supply and/or a higher-level control electronics on the electric bicycle, is provided on one of the circuit boards of the circuit board assembly.

16. The drive unit according to claim 14, wherein at least parts of a sensor technology, via which a torque is determinable, and/or an inertial measurement unit is provided on at least one of the circuit boards of the circuit board assembly.

17. The drive unit according to claim 14, wherein the electric motor drive comprises a rotor rotatable about a rotor axis and a transmission assembly whose transmission elements are coupled to the rotor of the electric motor drive, wherein the transmission elements are at least partially supported on a transmission carrier, on which the circuit board assembly is fixed.

18. The drive unit according to claim 17, wherein the at least one spacer element of the circuit board holder is formed with a through opening through which a fastening element passes, via which the circuit board assembly is fixed to the transmission carrier.

19. A method for assembling a circuit board assembly to a housing part of a drive unit for an electric bicycle,
wherein the circuit board assembly with two circuit boards and a circuit board holder is pre-assembled by fixing the two circuit boards to the circuit board holder and holding them at a distance from each other predetermined by the circuit board holder, and then assembling the pre-assembled circuit board assembly to the housing part.

20. The method according to claim 19, wherein the drive unit comprises an electric motor drive with a rotor rotatable about a rotor axis and a transmission assembly whose transmission elements are coupled to the rotor and are at least partially supported on a transmission carrier, wherein the transmission carrier is assembled to the housing part before the pre-assembled circuit board assembly and the pre-assembled circuit board assembly is fixed to the transmission carrier.
